(19) United States
(12) Patent Application Publication
(10) Pub. No.: US 2022/0020864 A1
(43) Pub. Date: Jan. 20, 2022

(54) THIN FILM TRANSISTOR, METHOD FOR MANUFACTURING THEREOF, ARRAY SUBSTRATE AND DISPLAY DEVICE

(71) Applicant: BOE Technology Group Co., Ltd., Beijing (CN)

(72) Inventors: Lizhen ZHANG, Beijing (CN); Zhi Wang, Beijing (CN); Yi Zhou, Beijing (CN); Wei He, Beijing (CN); Sheng XU, Beijing (CN); Huili Wu, Beijing (CN); Fang He, Beijing (CN); Xuefei Zhao, Beijing (CN); Shipei Li, Beijing (CN); Renquan Gu, Beijing (CN); Wusheng Li, Beijing (CN); Qi Yao, Beijing (CN); Jaiil Ryu, Beijing (CN)

(73) Assignee: BOE Technology Group Co., Ltd.

(21) Appl. No.: 17/210,615

(22) Filed: Mar. 24, 2021

(30) Foreign Application Priority Data
Jul. 16, 2020 (CN) 202010683733.5

(51) Int. Cl. H01L 29/66; H01L 29/06; H01L 29/417; H01L 29/786

(52) U.S. Cl. CPC H01L 29/66742; H01L 29/78663; H01L 29/41733; H01L 29/0673

(57) ABSTRACT

The present disclosure discloses a thin film transistor, a method for manufacturing thereof, an array substrate and a display device. The method for manufacturing the thin film transistor includes: forming a nanowire active layer on one side of a base substrate; forming a conductive protective layer on one side of the nanowire active layer away from the base substrate; forming an insulating layer on one side of the protective layer away from the nanowire active layer; etching the insulating layer using a dry etching process to form a first via hole exposing a first region of the protective layer and a second via hole exposing a second region of the protective layer; and forming a source-drain layer on one side of the insulating layer away from the protective layer, wherein the source-drain layer includes a first electrode and a second electrode.

### CROSS REFERENCE TO RELATED APPLICATIONS

The present disclosure claims priority to Chinese Patent Application No. 202010683733.5 filed with the China National Intellectual Property Administration on Jul. 16, 2020, the entire contents of which are incorporated herein by its reference.

### FIELD

The present disclosure relates to the technical field of semiconductors, in particular to a thin film transistor, a method for manufacturing thereof, an array substrate and a display device.

### BACKGROUND

The silicon nanowire has good ductility and elasticity, and can be applied in the field of flexible/stretchable electronics, such as wearable electronics, flexible displays, bionic electronics, artificial skin and other new applications.

However, there is the problem that a nanowire active layer is prone to being influenced by a dry etching process and is prone to being damaged when a via hole for conducting a source-drain and the nanowire active layer is formed through the dry etching process in the related art.

### SUMMARY

The present disclosure provides a thin film transistor, a method for manufacturing thereof, an array substrate and a display device.

An embodiment of the present disclosure provides a method for manufacturing a thin film transistor, including:

forming a nanowire active layer on one side of a base substrate; forming a conductive protective layer on one side of the nanowire active layer away from the base substrate;

forming an insulating layer on one side of the protective layer away from the nanowire active layer;

forming a first via hole exposing a first region of the protective layer and a second via hole exposing a second region of the protective layer by etching the insulating layer using a dry etching process, wherein the first region and the second region are not overlapped with each other

forming a source-drain layer on one side of the insulating layer away from the protective layer, wherein the source-drain layer includes a first electrode and a second electrode, the first electrode is electrically conducted with the nanowire active layer through the first via hole, and the second electrode is electrically conducted with the nanowire active layer through the second via hole.

In a possible implementation, after etching the insulating layer using the dry etching process, and before forming the source-drain layer on the side of the insulating layer away from the protective layer, the method further includes: removing the protective layer in the first region, and removing the protective layer in the second region by etching the protective layer using a wet etching process.

In a possible implementation, the forming the nanowire active layer on the side of the base substrate includes:

forming a patterned first film layer with at least one guide groove on one side of the base substrate;

forming metal guide particles at one end of the guide groove;

forming an amorphous silicon thin film on one side of the metal guide particles away from the first film layer, and annealing the amorphous silicon thin film to form a silicon nanowire in the guide groove; and

forming the nanowire active layer by patterning the annealed amorphous silicon thin film, wherein a pattern of the nanowire active layer is complementary to that of the first film layer.

In a possible implementation, the forming the metal guide particles at the end of the guide groove includes:

forming a second thin film on one side of the first film layer away from the base substrate; removing the second thin film in other regions except the region where one end of the groove is located; and

forming the metal guide particles by performing hydrogen plasma treatment on the retained second thin film.

In a possible implementation, the forming the second thin film on one side of the first film layer away from the base substrate includes:

forming indium tin oxide on the side of the first film layer away from the base substrate.

In a possible implementation, the forming the conductive protective layer on the side of the nanowire active layer away from the base substrate includes:

forming molybdenum, copper, aluminum or indium tin oxide on one side of the nanowire active layer away from the base substrate.

In a possible implementation, the forming the insulating layer on one side of the protective layer away from the nanowire active layer includes:

forming a gate insulating layer on one side of the protective layer away from the nanowire active layer; and

forming an interlayer dielectric layer on one side of the gate insulating layer away from the nanowire active layer.

In a possible implementation, after the forming the gate insulating layer on the side of the protective layer away from the nanowire active layer, and before the forming the interlayer dielectric layer on the side of the gate insulating layer away from the nanowire active layer, the method further includes:

forming a gate on one side of the gate insulating layer away from the nanowire active layer.

An embodiment of the present disclosure further provides a thin film transistor, including:

a base substrate;

a nanowire active layer on one side of the base substrate;

a conductive protective layer on one side of the nanowire active layer away from the base substrate;

an insulating layer on one side of the protective layer away from the nanowire active layer, wherein the insulating layer has a first via hole exposing a first region of the protective layer and a second via hole exposing a second region of the protective layer, and the first region and the second region are not overlapped with each other; and

a source-drain layer on one side of the insulating layer away from the protective layer, wherein the source-drain layer includes a first electrode and a second electrode, the first electrode is electrically conducted with the nanowire active layer through the first via hole, and the second electrode is electrically conducted with the nanowire active layer through the second via hole.

In a possible implementation, the protective layer has a first hollowed-out structure in the first region, and the protective layer has a second hollowed-out structure in the second region; an orthographic projection of the first hollowed-out structure on the base substrate is coincided with an orthographic projection of the first via hole on the base substrate, and an orthographic projection of the second hollowed-out structure on the base substrate is coincided with an orthographic projection of the second via hole on the base substrate.

In a possible implementation, the thin film transistor further includes: a patterned first film layer between the base substrate and the nanowire active layer, wherein the first film layer has at least one guide groove, and a pattern of the first film layer is complementary to that of the nanowire active layer.

In a possible implementation, metal guide particles are formed in one end of the guide groove by hydrogen plasma treatment on a second thin film.

In a possible implementation, a material of the second thin film is indium tin oxide;

and the nanowire active layer includes the metal guide particles of indium.

In a possible implementation, a material of the protective layer is molybdenum, copper, aluminum or indium tin oxide.

In a possible implementation, the insulating layer includes a gate insulating layer and an interlayer dielectric layer on one side of the gate insulating layer away from the nanowire active layer; and

a gate is further arranged between the gate insulating layer and the interlayer dielectric layer.

An embodiment of the present disclosure further provides an array substrate, including the thin film transistor provided by an embodiment of the present disclosure.

An embodiment of the present disclosure further provides a display device, including the array substrate provided by an embodiment of the present disclosure.

### BRIEF DESCRIPTION OF THE DRAWINGS

FIG. 1 is a flowchart of a method for manufacturing a thin film transistor provided by an embodiment of the present disclosure.

FIG. 2 is a flowchart of a specific method for manufacturing a thin film transistor provided by an embodiment of the present disclosure.

FIG. 3 is a flowchart of another specific method for manufacturing a thin film transistor provided by an embodiment of the present disclosure.

FIG. 4 is a schematic top view of a thin film transistor with a prepared first film layer according to an embodiment of the present disclosure.

FIG. 5 is a schematic top view of a thin film transistor with a prepared second thin film according to an embodiment of the present disclosure.

FIG. 6A is a schematic top view of a thin film transistor with a prepared nanowire active layer according to an embodiment of the present disclosure.

FIG. 6B is a schematic sectional view of a thin film transistor with a prepared nanowire active layer according to an embodiment of the present disclosure.

FIG. 6C is a schematic top view of a thin film transistor with a prepared patterned nanowire active layer according to an embodiment of the present disclosure.

FIG. 7A is a schematic top view of a thin film transistor with a prepared protective layer according to an embodiment of the present disclosure.

FIG. 7B is a schematic sectional view of a thin film transistor with a prepared protective layer according to an embodiment of the present disclosure.

FIG. 8A is a schematic top view of a thin film transistor with a prepared gate insulating layer according to an embodiment of the present disclosure.

FIG. 8B is a schematic sectional view of a thin film transistor with a prepared gate insulating layer according to an embodiment of the present disclosure.

FIG. 9A is a schematic top view of a thin film transistor with a prepared gate according to an embodiment of the present disclosure.

FIG. 9B is a schematic sectional view of a thin film transistor with a prepared gate according to an embodiment of the present disclosure.

FIG. 10A is a schematic top view of a thin film transistor with a prepared interlayer dielectric layer according to an embodiment of the present disclosure.

FIG. 10B is a schematic sectional view of a thin film transistor with a prepared interlayer dielectric layer according to an embodiment of the present disclosure.

FIG. 11A is a schematic top view of a thin film transistor with a prepared first via hole and second via hole by dry etching according to an embodiment of the present disclosure.

FIG. 11B is a schematic sectional view of a thin film transistor with a prepared first via hole and second via hole by dry etching according to an embodiment of the present disclosure.

FIG. 12A is a schematic top view of a thin film transistor with a protective layer of a first region and a second region removed by wet etching according to an embodiment of the present disclosure.

FIG. 12B is a schematic sectional view of a thin film transistor with a protective layer of a first region and a second region removed by wet etching according to an embodiment of the present disclosure.

FIG. 13A is a schematic top view of a thin film transistor with a prepared source-drain layer according to an embodiment of the present disclosure.

FIG. 13B is a schematic sectional view of a protective layer with a prepared source-drain layer according to an embodiment of the present disclosure.

FIG. 14 is a schematic sectional view of a thin film transistor with a protective layer in a first region and a second region retained according to an embodiment of the present disclosure.

FIG. 15 is a schematic sectional view of a bottom gate thin film transistor provided by an embodiment of the present disclosure.

FIG. 16 is a schematic top view of an array substrate with a prepared first film layer provided by an embodiment of the present disclosure.

FIG. 17 is a schematic top view of an array substrate with a prepared nanowire active layer provided by an embodiment of the present disclosure.

FIG. 18 is a schematic top view of an array substrate with a prepared protective layer provided by an embodiment of the present disclosure.

### DETAILED DESCRIPTION OF THE EMBODIMENTS

In order to make the purpose, technical solutions and advantages of the embodiments of the present disclosure more clear, the technical solutions of the embodiments of the present disclosure will be described clearly and completely in conjunction with the drawings of the embodiments of the present disclosure. Obviously, the described embodiments are part of the embodiments of the present disclosure, but not all the embodiments. On the basis of the described embodiments of the present disclosure, all other embodiments obtained by a person of ordinary skill in the art without inventive efforts fall within the protection scope of the present disclosure.

Unless otherwise defined, the technical or scientific terms used in the present disclosure shall have the usual meanings understood by a person of ordinary skill in the art to which the present disclosure belongs. The words “first”, “second” and the like used in the present disclosure do not indicate any order, quantity or importance, but are only used to distinguish different components. The word “including” or “comprising” and the like, means that an element or item preceding the word comprises an element or item listed after the word and the equivalent thereof, without excluding other elements or items. The word “connection” or “coupling” and the like is not restricted to physical or mechanical connection, but may include electrical connection, whether direct or indirect. The words “up”, “down”, “left”, “right” and the like are only used to indicate the relative positional relationship. When the absolute position of the described object changes, the relative positional relationship may also change accordingly.

In order to keep the following descriptions of the embodiments of the present disclosure clear and concise, the present disclosure omits detailed descriptions of known functions and known components.

Amorphous silicon (a-Si) thin film transistors have failed to meet 8K technical requirements due to too small mobility (<1 cm²V⁻¹S⁻¹). A Low Temperature Poly-Silicon (LTPS) technique is limited by laser beam size and process cost, and thus is limited in use. A planar silicon nanowire has high mobility (>100 cm²V⁻¹S⁻¹), large-area preparation and low cost, and thus becomes a potential application technique for upgrading an a-Si production line. In addition, the silicon nanowire has good ductility and elasticity, and can be applied in the field of flexible/stretchable electronics, such as wearable electronics, flexible displays, bionic electronics, artificial skin and other new applications.

An In-Plane Solid-Liquid-Solid (IP-SLS) growth technique is a new type of planar silicon nanowire growth technique, which is a method for growing nanowires with metal catalysis. Unlike Vapor-Liquid-Solid (VLS) growth, which requires a gaseous precursor (SiH4), a precursor (a-Si:H) in this technique is solid. Growth mechanism: an Indium Tin Oxide (ITO) substrate is processed by hydrogen plasma (H plasma) to form In nano particles on the surface, and then a layer of solid a-Si:H is covered as a precursor source. Then, the substrate is heated, and when the temperature of the substrate is heated to be higher than that of an In/Si alloy, metal catalytic particles start to absorb surrounding a-Si:H, and crystalline silicon nanowire crystal nuclei are precipitated on one side of metal catalytic liquid drops after the concentration of Si atoms in the catalytic liquid drops reaches a supersaturated state. Then, on the basis of the nanocrystal nuclei, the metal catalytic liquid drops continuously absorb a-Si:H to form the silicon nanowire.

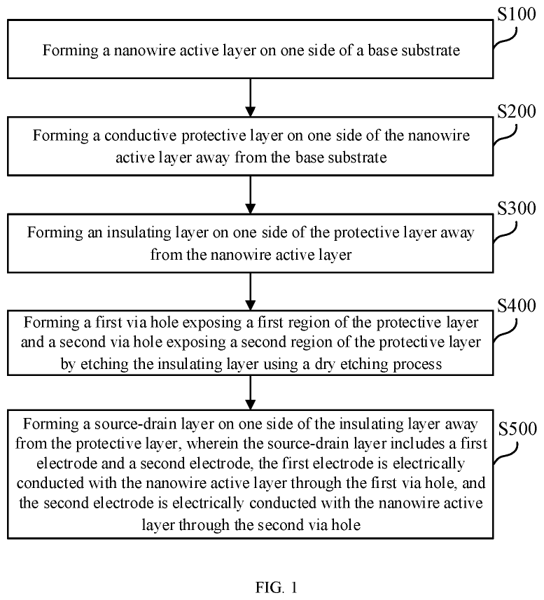

Referring to FIG. 1, an embodiment of the present disclosure provides a method for manufacturing a thin film transistor, including the following steps.

Step S100, forming a nanowire active layer on one side of a base substrate, wherein the base substrate may specifically be a glass base substrate, and the nanowire active layer may specifically be a silicon nanowire active layer.

Step S200, forming a conductive protective layer on one side of the nanowire active layer away from the base substrate. In some embodiments, step S200 may be: molybdenum, copper, aluminum or indium tin oxide are formed on the side of the nanowire active layer away from the base substrate, that is, a material of the protective layer may specifically be molybdenum, copper, aluminum or indium tin oxide; and the molybdenum, copper, aluminum or indium tin oxide can block gas for dry etching, protect the silicon-based nanowire from being damaged and conduct current.

Step S300, forming an insulating layer on one side of the protective layer away from the nanowire active layer.

Step S400, forming a first via hole exposing a first region of the protective layer and a second via hole exposing a second region of the protective layer by etching the insulating layer using a dry etching process, wherein the first region and the second region are not overlapped with each other.

Step S500, forming a source-drain layer on one side of the insulating layer away from the protective layer, wherein the source-drain layer includes a first electrode and a second electrode, the first electrode is electrically conducted with the nanowire active layer through the first via hole, and the second electrode is electrically conducted with the nanowire active layer through the second via hole. In some embodiments, the first electrode may be a source, and the second electrode may be a drain.

In the method for manufacturing the thin film transistor provided by the embodiments of the present disclosure, before the via hole for electrically conducting the source-drain layer and the nanowire active layer is formed on the insulating layer by the dry etching process, the conductive protective layer is manufactured first; during the formation of the via hole, the protective layer can block gas used in the dry etching process, protect the nanowire active layer from being damaged and conduct current, and further solve the problem that the nanowire active layer is prone to being influenced by the dry etching process to cause damage to the nanowire active layer when the via hole for conducting the source-drain and the nanowire active layer is formed through the dry etching process in the related art.

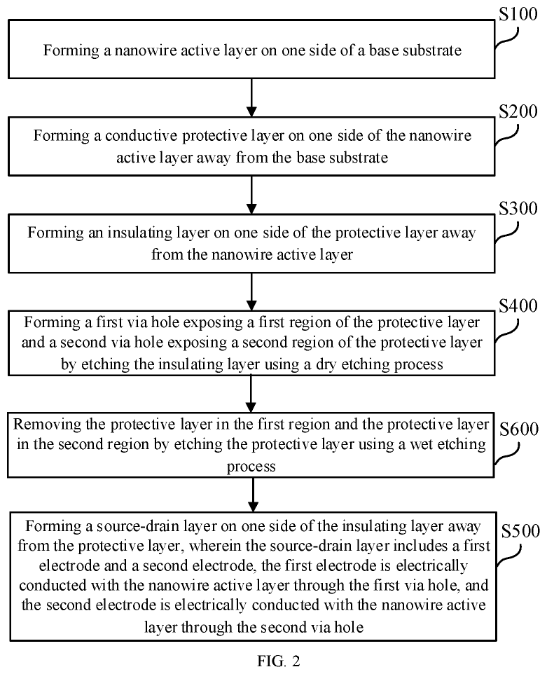

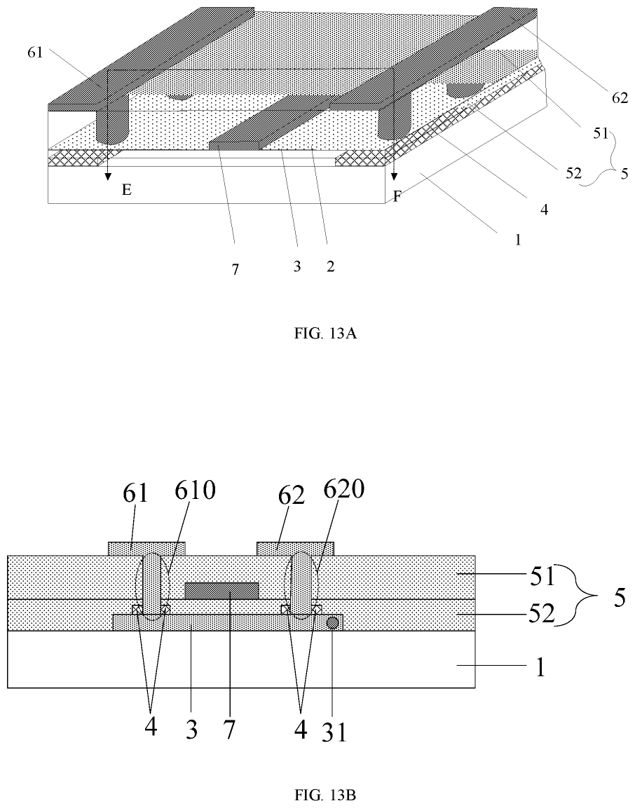

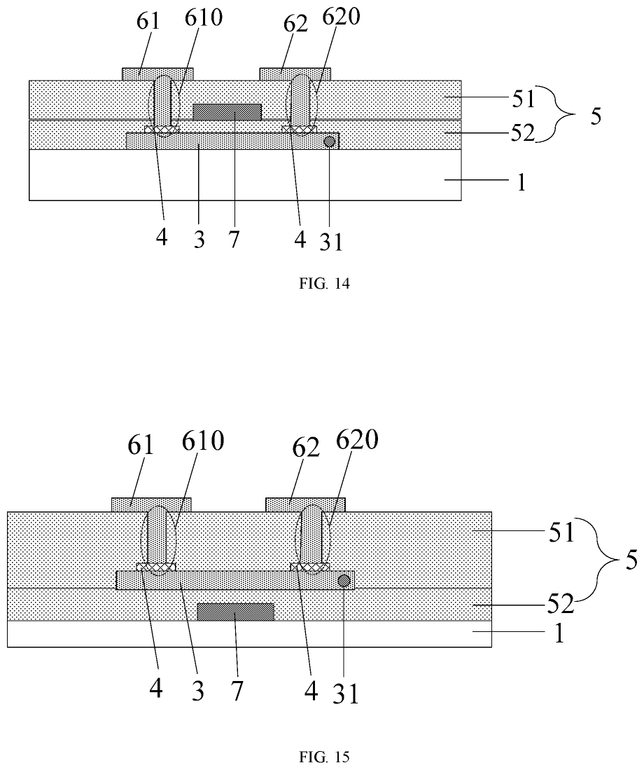

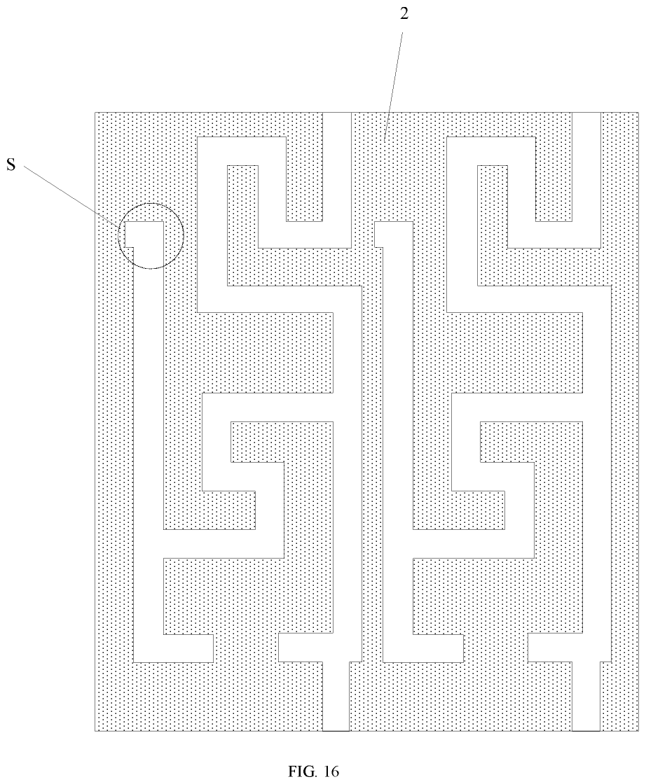

In specific implementation, as shown in FIG. 14, since the protective layer 4 is a conductive film layer, the protective layer 4 can be retained when manufacturing the thin film transistor to simplify a process for manufacturing the thin film transistor. In another possible implementation, as shown in FIG. 13B, the protective layer 4 can also be removed. In some embodiments, as shown in FIG. 2, after the step S400 and before the step S500, that is, after etching the insulating layer using the dry etching process, and before forming the source-drain layer on the side of the insulating layer away from the protective layer, the method further includes: step S600, removing the protective layer in the first region and the protective layer in the second region by etching the protective layer using a wet etching process. In the embodiment of the present disclosure, after forming the via hole by etching the insulating layer, the protective layer in the first region and the second region is removed by using the wet etching process on the protective layer, so that the subsequently formed first electrode and second electrode can directly make contact with the nanowire active layer. Compared with retaining the protective layer in the first region and the second region, only the existence of the contact resistance between the metal and the nanowire active layer has the advantage of lower contact resistance.

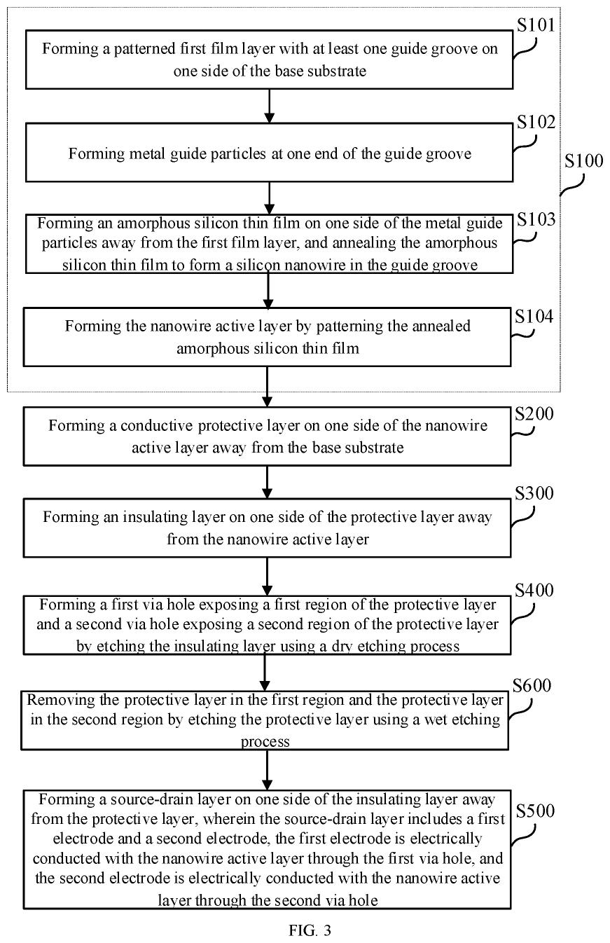

In specific implementation, the IP-SLS growth technique can be adopted to form the nanowire active layer. In some embodiments, referring to FIG. 3, regarding step S100, forming the nanowire active layer on the side of the base substrate includes the following steps.

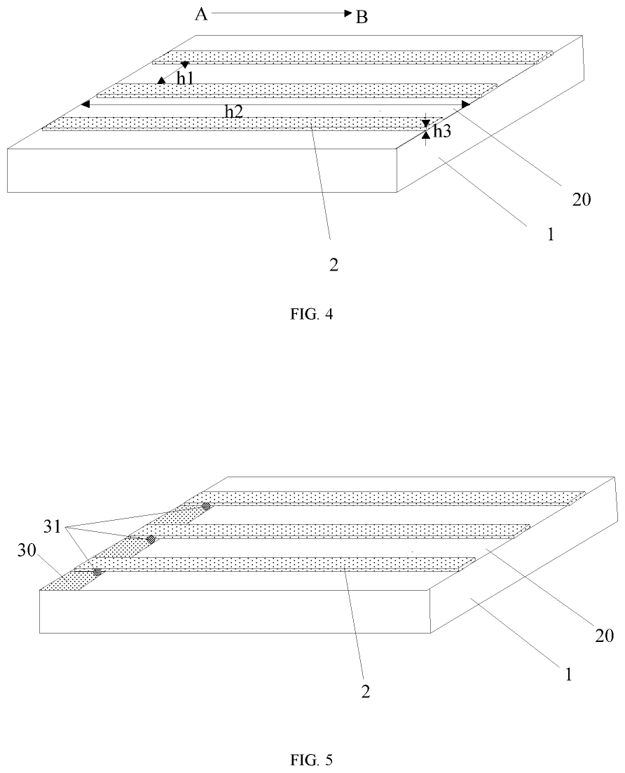

Step S101, forming a patterned first film layer with at least one guide groove on one side of the base substrate. In some embodiments, the first film layer may be formed by depositing a layer of a first thin film, and then patterning the first thin film; a material of the first film layer may specifically be silicon dioxide (SiO2); for a single thin film transistor, as shown in FIG. 4 which is a schematic diagram after the first film layer is formed, each thin film transistor may specifically include a plurality of guide grooves 20, for example, each thin film transistor may specifically include 3-8 guide grooves 20; the plurality of guide grooves 20 may specifically extend in the same direction, for example, all extend in a first direction AB; the plurality of guide grooves 20 have the same width h1 in a direction perpendicular to the first direction AB and parallel to the base substrate, the same extension length h2 in a direction parallel to the first direction AB, and the same depth h3 in a direction perpendicular to the base substrate 1; a distance between any two adjacent guide grooves 20 is the same; and certainly, in specific implementation, a pattern of the first film layer may also be other patterns, which is not limited in the present disclosure.

Step S102, forming metal guide particles at one end of the guide groove. For example, as shown in FIG. 5, the metal guide particles 31 are formed at the left end of each guide groove 20. In some embodiments, the step S102 may include: step S1021, forming a second thin film 30 on one side of the first film layer 2 away from the base substrate 1, wherein a material of the second thin film 30 may specifically be indium tin oxide; step S1022, removing the second thin film 30 in other regions except the region where one end of the guide groove 20 is located; and step S1023, forming In metal guide particles, i.e., metal guide particles 31, by performing hydrogen plasma treatment on the retained second thin film 30.

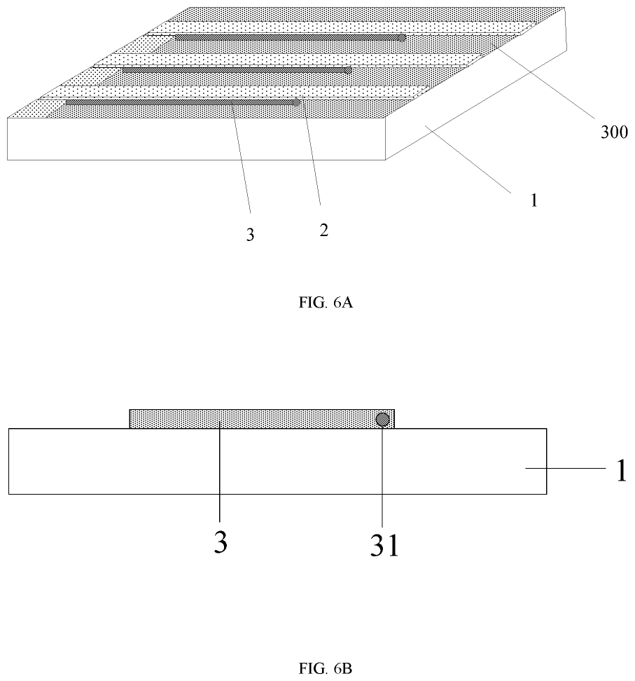

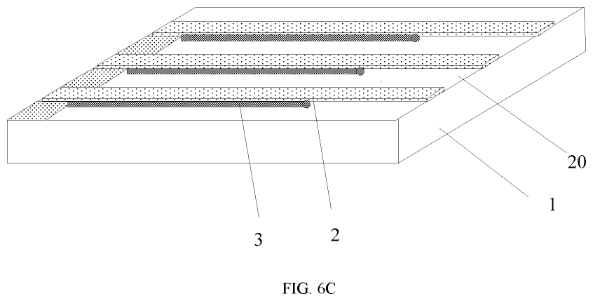

Step S103, forming an amorphous silicon thin film 300 on one side of the metal guide particles 31 away from the first film layer 2, and annealing the amorphous silicon thin film 300 to form a silicon nanowire (also the nanowire active layer 3) in the guide groove 20, as shown in FIG. 6A.

Step S104, forming the nanowire active layer by patterning the annealed amorphous silicon thin film, wherein a pattern of the nanowire active layer is complementary to that of the first film layer. The patterning of the nanowire active layer in this step can remove the silicon nanowire grown in the region outside the guide groove, and further regularize the pattern of the nanowire active layer.

In specific implementation, the thin film transistor in an embodiment of the present disclosure may be a top gate thin film transistor. The insulating layer in step S100 specifically may include a gate insulating layer and an interlayer dielectric layer on one side of the gate insulating layer away from the protective layer. That is, specifically, regarding step S300, forming the insulating layer on one side of the protective layer away from the nanowire active layer includes: forming the gate insulating layer on one side of the protective layer away from the nanowire active layer; and forming the interlayer dielectric layer on one side of the gate insulating layer away from the nanowire active layer. In some embodiments, after forming the gate insulating layer on one side of the protective layer away from the nanowire active layer, and before forming the interlayer dielectric layer on one side of the gate insulating layer away from the nanowire active layer, the method further includes: forming a gate on one side of the gate insulating layer away from the nanowire active layer.

In order to more clearly understand the method for manufacturing the thin film transistor provided by an embodiment of the present disclosure, the thin film transistor provided by the embodiment of the present disclosure is further described in detail below with reference to the drawings as follows.

In a possible implementation, the method for manufacturing the thin film transistor by removing a protective layer in a first region and a second region may specifically be as follows.

Step 1, forming a patterned first film layer 2 with at least one guide groove 20 (i.e., a guide step) on one side of a base substrate 1. In some embodiments, a silicon dioxide thin film can be deposited first and patterned to form the guide groove 20, as shown in FIG. 4.

Step 2, forming a second thin film 30 (specifically, it may be indium tin oxide (ITO) thin film) on one side of the first film layer 2 away from the base substrate 1, wherein a material of the second thin film 30 may specifically be indium tin oxide; removing the second thin film 30 in other regions except a region where one end of the guide groove 20 is located; and forming metal guide particles 31 by performing hydrogen plasma treatment (H2 plasma) on the retained second thin film 30, as shown in FIG. 5.

Step 3, forming an amorphous silicon thin film 300 on one side of the metal guide particles 31 away from the first film layer, and annealing the amorphous silicon thin film 300 to form a silicon nanowire (also a nanowire active layer 3) in the guide groove 20, as shown in FIGS. 6A and 6B; forming the nanowire active layer 3 by patterning the annealed amorphous silicon thin film 300, as shown in FIG. 6C, wherein a pattern of the nanowire active layer 3 is complementary to that of the first film layer 2, that is, the nanowire active layer 3 is located in the guide groove 20 without the first film layer 2.

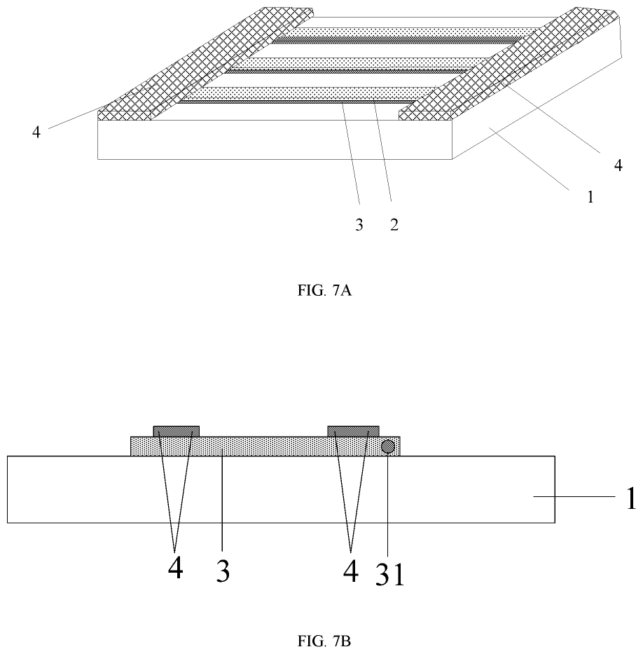

Step 4, forming a conductive protective layer 4 on one side of the nanowire active layer 3 away from the base substrate 1. In some embodiments, a metal layer (wet-etchable metals and alloys and metal oxides, such as Mo, ITO, Cu, Al) can be deposited, wet-etched, and patterned, as shown in FIGS. 7A and 7B.

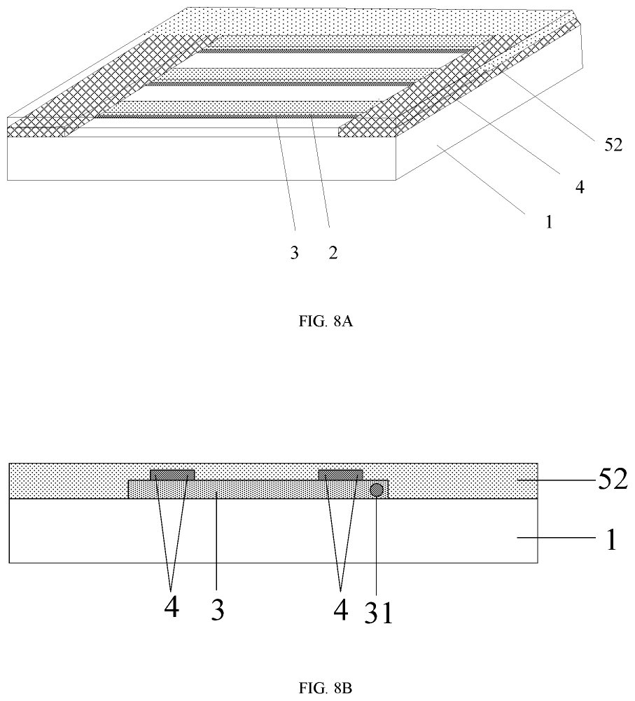

Step 5, depositing a gate insulating layer 52, as shown in FIGS. 8A and 8B.

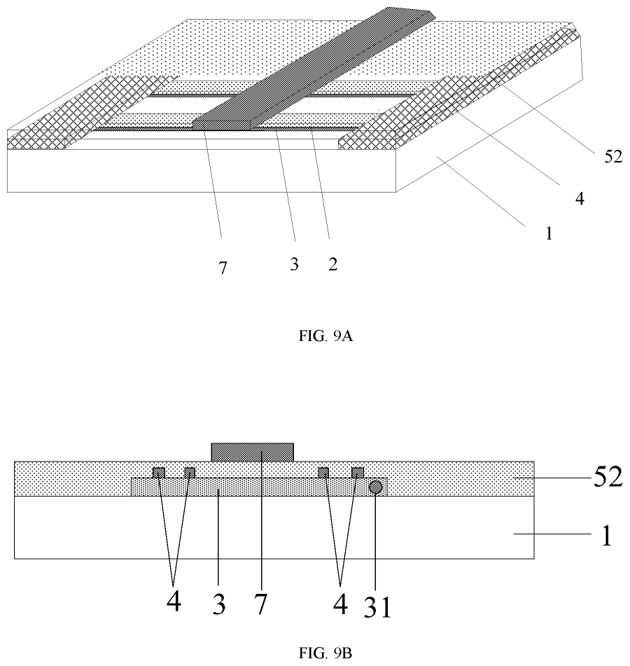

Step 6, depositing and patterning a gate metal thin film to form a gate 7, as shown in FIGS. 9A and 9B.

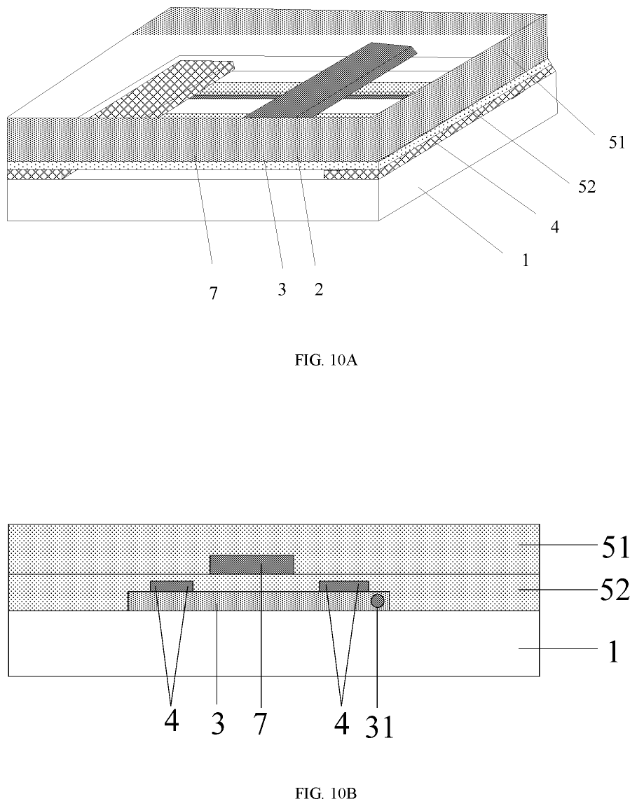

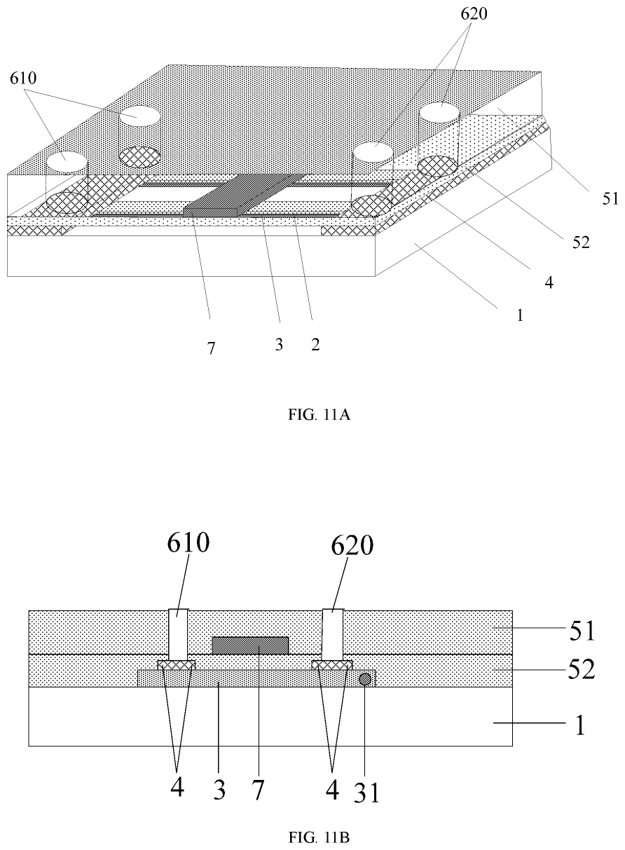

Step 7, depositing an interlayer dielectric layer 51, as shown in FIGS.10A and 10B.

Step 8, forming a first via hole 610 and a second via hole 620 by dry-etching the interlayer dielectric layer 51 and by trepanning the interlayer dielectric layer 51 to the protective layer 4, as shown in FIGS. 11A and 11B.

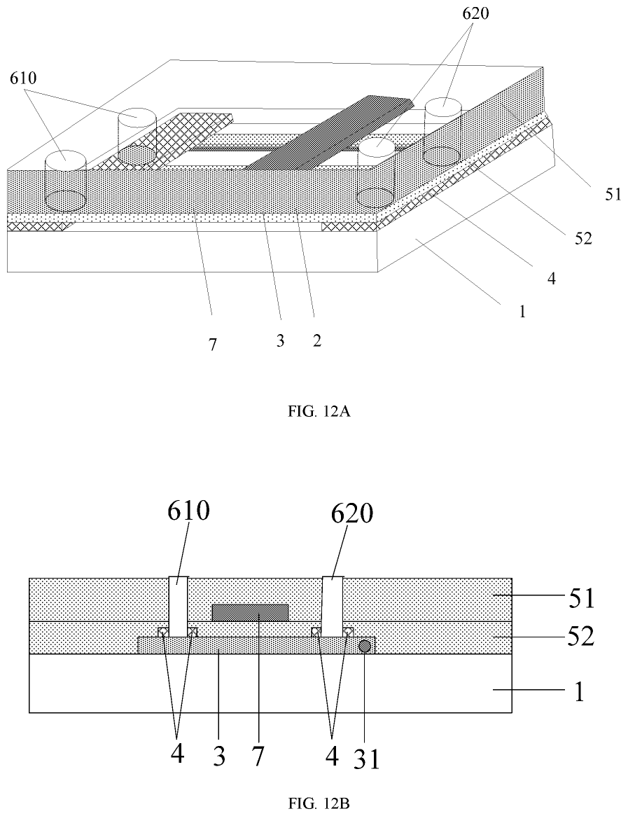

Step 9, removing the protective layer 4 in the first region (i.e., the region where the first via hole 610 is located) and the protective layer 4 in the second region (i.e., the region where the second via hole 620 is located),by etching the protective layer 4 using a wet etching process, as shown in FIGS. 12A and 12B.

Step 10, forming a source-drain layer (the specific material may be Ti/Al/Ti) on one side of the interlayer dielectric layer 51 away from the gate 7, and dry etching and patterning the same, wherein the source-drain layer includes a first electrode 61 and a second electrode 62, the first electrode 61 is electrically conducted with the nanowire active layer 3 through the first via hole 610, and the second electrode 62 is electrically conducted with the nanowire active layer 3 through the second via hole 620. In some embodiments, the first electrode 61 may be electrically conducted with the nanowire active layer 3 through the plurality of first via holes 610, and the second electrode 62 may be electrically conducted with the nanowire active layer 3 through the plurality of second via holes 620, as shown in FIGS. 13A and 13B, wherein FIG. 13B is a schematic cross-sectional view of FIG. 13A along a dotted line EF.

In another possible implementation, the method for manufacturing the thin film transistor by retaining the protective layer 3 in the first region and the second region may specifically be as follows.

Step 1, forming a patterned first film layer 2 with at least one guide groove 20 (a guide step) on one side of a base substrate 1. In some embodiments a silicon dioxide thin film can be deposited first and patterned to form the guide groove 20, as shown in FIG. 4.

Step 2, forming a second thin film 30 (specifically, it may be indium tin oxide (ITO) thin film) on one side of the first film layer 2 away from the base substrate 1, wherein a material of the second thin film 30 may specifically be indium tin oxide; removing the second thin film 30 in other regions except the region where one end of the guide groove 20 is located; and forming metal guide particles 31 by performing hydrogen plasma treatment (H2 plasma) on the retained second thin film 30, as shown in FIG. 5.

Step 3, forming an amorphous silicon thin film 300 on one side of the metal guide particles 31 away from the first film layer, and annealing the amorphous silicon thin film 300 to form a silicon nanowire (also a nanowire active layer 3) in the guide groove 20, as shown in FIGS. 6A and 6B; and forming the nanowire active layer 3 by patterning the annealed amorphous silicon thin film 300, wherein a pattern of the nanowire active layer 3 is complementary to that of the first film layer 2.

Step 4, forming a conductive protective layer 4 on one side of the nanowire active layer 3 away from the base substrate 1. In some embodiments, a metal layer (wet-etchable metals and alloys and metal oxides such as Mo, ITO, Cu, Al) can be deposited, wet-etched, and patterned, as shown in FIGS. 7A and 7B.

Step 5, depositing a gate insulating layer 52, as shown in FIGS. 8A and 8B.

Step 6, depositing and patterning a gate metal thin film to form a gate 7, as shown in FIGS. 9A and 9B.

Step 7, depositing an interlayer dielectric layer 51, as shown in FIGS.10A and 10B.

Step 8, forming a first via hole 610 and a second via hole 620 by dry-etching the interlayer dielectric layer 51 and by trepanning the interlayer dielectric layer 51 to the protective layer 4, as shown in FIGS. 11A and 11B.

Step 9, forming a source-drain layer (the specific material may be Ti/Al/Ti) on one side of the interlayer dielectric layer 51 away from the gate 7, and dry etching and patterning the same, wherein the source-drain layer includes a first electrode 61 and a second electrode 62, the first electrode 61 is electrically conducted with the nanowire active layer 3 through the first via hole 610, and the second electrode 62 is electrically conducted with the nanowire active layer 3 through the second via hole 620. As shown in FIG. 14, that is, there is no need to remove the protective layer 4 in the region where the first via hole 610 and the second via hole 620 are located.

On the basis of the same inventive concept, an embodiment of the present disclosure further provides a thin film transistor. As shown in FIG. 14, the thin film transistor can be obtained by the method provided by the embodiment of the present disclosure. As shown in the figure, the thin film transistor may specifically include:

a base substrate 1, wherein a material of the base substrate 1 may specifically be glass;

a nanowire active layer 3 on one side of the base substrate 1, wherein a material of the nanowire active layer 3 may specifically be a silicon nanowire active layer;

a conductive protective layer 4 on one side of the nanowire active layer 3 away from the base substrate 1;

an insulating layer 5 on one side of the protective layer 4 away from the nanowire active layer 3, wherein the insulating layer 5 has a first via hole 610 exposing a first region of the protective layer 4 and a second via hole 620 exposing a second region of the protective layer 4, and the first region and the second region are not overlapped with each other; and

a source-drain layer on one side of the insulating layer 5 away from the protective layer 4, wherein the source-drain layer includes a first electrode 61 and a second electrode 62, the first electrode 61 is electrically conducted with the nanowire active layer 3 through the first via hole 610 and specifically may be electrically conducted with the nanowire active layer 3 through the protective layer 4, and the second electrode 62 is electrically conducted with the nanowire active layer 3 through the second via hole 620 and specifically may be electrically conducted with the nanowire active layer 3 through the protective layer 4.

The thin film transistor provided by an embodiment of the present disclosure includes: the nanowire active layer 3 on one side of the base substrate 1; the conductive protective layer 4 on one side of the nanowire active layer 3 away from the base substrate 1; and the source-drain layer on one side of the insulating layer 5 away from the protective layer 4, wherein the source-drain layer includes a first electrode 61 and a second electrode 62, the first electrode 61 is electrically conducted with the nanowire active layer 3 through the first via hole 610, and the second electrode 62 is electrically conducted with the nanowire active layer 3 through the second via hole 620. In other words, when manufacturing the thin film transistor, before the via hole for electrically conducting the source-drain layer and the nanowire active layer is formed on the insulating layer by a dry etching process, the conductive protective layer is manufactured first; during the formation of the via hole, the protective layer can block gas used in the dry etching process, protect the nanowire active layer from being damaged and conduct current, and further solve the problem that the nanowire active layer is prone to being influenced by the dry etching process to cause damage to the nanowire active layer when the via hole for conducting a source-drain and the nanowire active layer is formed through the dry etching process in the related art.

In specific implementation, since the protective layer 4 is a conductive film layer, the protective layer 4 can be retained when manufacturing the thin film transistor to simplify a process for manufacturing the thin film transistor. The structural view of the formed thin film transistor may be as shown in FIG. 14. In another possible implementation, the protective layer 4 in the region where the first via hole 610 and the second via hole 620 are located may also be removed. In some embodiments, the structural view of the formed thin film transistor may be shown in FIG. 13B. In other words, the protective layer 4 has a first hollowed-out structure in the first region, and the protective layer 4 has a second hollowed-out structure in the second region; an orthographic projection of the first hollowed-out structure on the base substrate 1 is coincided with an orthographic projection of the first via hole 610 on the base substrate 1, and an orthographic projection of the second hollowed-out structure on the base substrate 1 is coincided with an orthographic projection of the second via hole 620 on the base substrate 1. In the embodiment of the present disclosure, the protective layer 4 has the first hollowed-out structure in the first region, and the protective layer 4 has the second hollowed-out structure in the second region. Compared with retaining the protective layer 4 in the first region and the second region, the first electrode 61 and the second electrode 62 directly make contact with the nanowire active layer 3, only the existence of the contact resistance between the metal and the nanowire active layer 3 has the advantage of lower contact resistance is achieved.

In specific implementation, as shown in FIG. 4, the thin film transistor further includes: a patterned first film layer 2 between the base substrate 1 and the nanowire active layer 3, wherein the first film layer 2 has at least one guide groove 20, and a pattern of the first film layer 2 is complementary to that of the nanowire active layer 3. A material of the first film layer 2 may specifically be silicon dioxide (Si02); for the single thin film transistor, each thin film transistor may specifically include the plurality of guide grooves 20, for example, each thin film transistor may specifically include 3-8 guide grooves 20; the plurality of guide grooves 20 may specifically extend in the same direction, for example, all extend in a first direction AB (for example, a transverse direction in FIG. 4)); and the plurality of guide grooves 20 have the same width h1 in a direction perpendicular to the first direction AB and parallel to the base substrate, the same extension length h2 in a direction parallel to the first direction AB, and the same depth h3 in a direction perpendicular to the base substrate 1. A distance between any two adjacent guide grooves 20 is the same.

In specific implementation, as shown in FIG. 5, metal guide particles are formed in one end of the guide groove 20 (for example, the left end of the guide groove 20 in FIG. 5) by hydrogen plasma treatment on a second thin film 30. In some embodiments, a material of the second thin film 30 is indium tin oxide; and the nanowire active layer 3 includes indium metal guide particles 31 therein. In an embodiment of the present disclosure, the metal guide particles after hydrogen plasma treatment is formed in one end of the guide groove 20, and a silicon nanowire active layer can be formed by the guide of the indium metal guide particles during manufacture in a subsequent process procedure.

In specific implementation, a material of the protective layer 4 is molybdenum, copper, aluminum or indium tin oxide. In an embodiment of the present disclosure, the molybdenum, copper, aluminum or indium tin oxide block gas for dry etching, has a good effect of protecting the silicon-based nanowire from being damaged and can conduct current.

In specific implementation, the thin film transistor provided by an embodiment of the present disclosure may be a top gate thin film transistor, as shown in FIG. 14, the insulating layer 5 includes a gate insulating layer 52 and an interlayer dielectric layer 51 on one side of the gate insulating layer 52 away from the nanowire active layer 3; and a gate 7 is further arranged between the gate insulating layer 52 and the interlayer dielectric layer 51. In some embodiments, the thin film transistor may also be a bottom gate thin film transistor, as shown in FIG. 15, a gate 7 may be arranged between the base substrate 1 and the nanowire active layer 3, and a gate insulating layer 52 is further arranged between the gate 7 and the nanowire active layer 3.

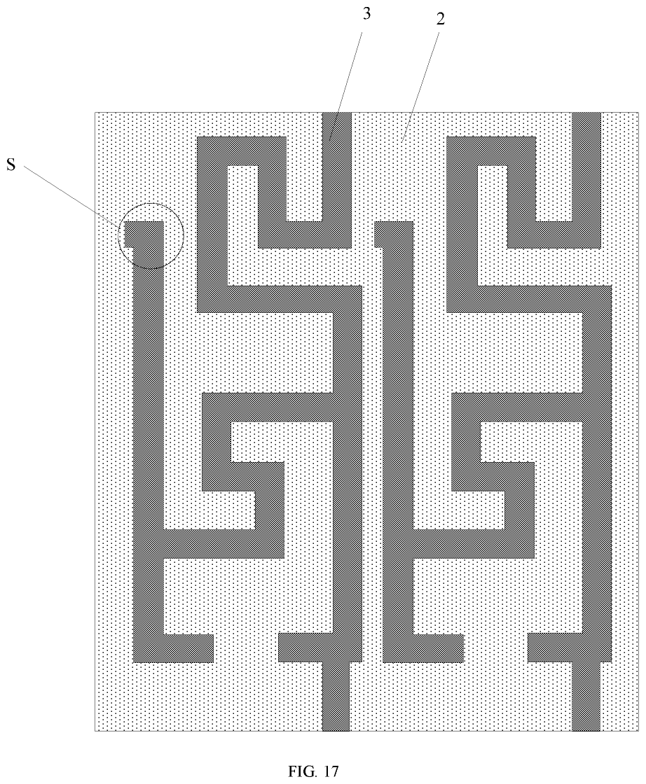

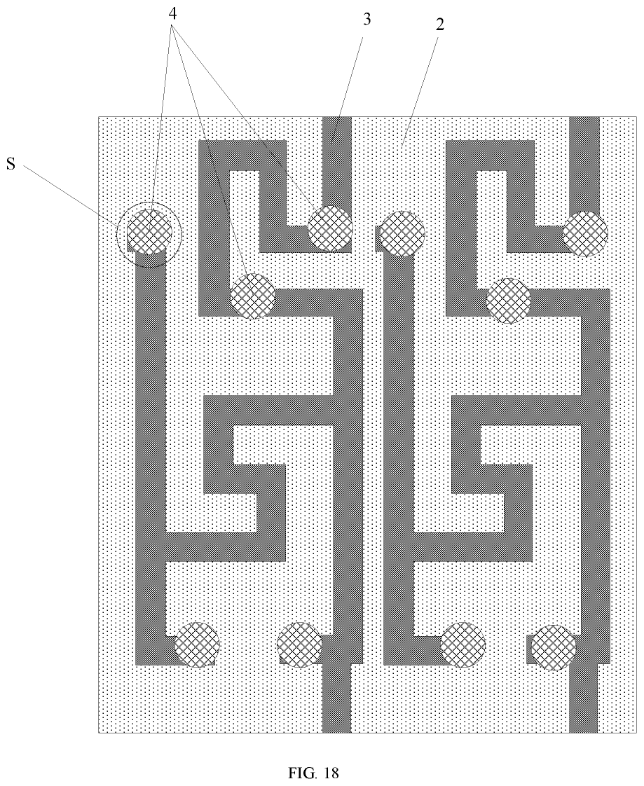

An embodiment of the present disclosure further provides an array substrate, including the thin film transistors provided by the embodiments of the present disclosure. In some embodiments, since the array substrate is generally provided with a plurality of thin film transistors at the same time, respective film layers of the plurality of thin film transistors are formed synchronously, and then a film layer shared by the plurality of transistors is formed on the array substrate, for example, a shared patterned first film layer 2, as shown in FIG. 16, wherein the enlarged structure diagram of the first film layer 2 at the position where the transistor is arranged (for example, the position of a dashed circle S in FIG. 16) can be seen by referring to FIG. 4; a shared patterned nanowire active layer 3, as shown in FIG. 17, wherein the enlarged structure diagram of the active nanowire layer 3 at the position where the transistor is arranged (for example, the position of a dashed circle S in FIG. 17) when the active nanowire layer 3 is grown can be seen by referring to FIG. 6C; and a shared patterned protective layer 4, as shown in FIG. 18, wherein the enlarged structure diagram of the protective layer 4 at the position where the transistor is arranged (for example, the position of a dashed circle S in FIG. 18) can be seen by referring to FIG. 7A, and the protective layer 4 may not be arranged at other positions where the thin film transistor is not arranged.

An embodiment of the present disclosure further provides a display device, including the array substrate provided by the embodiment of the present disclosure.

The embodiments of the present disclosure have the following beneficial effects: in the method of the thin film transistor provided by the embodiments of the present disclosure, before the via hole for electrically conducting the source-drain layer and the nanowire active layer is formed on the insulating layer by the dry etching process, the conductive protective layer is manufactured first; during the formation of the via hole, the protective layer can block gas used in the dry etching process, protect the nanowire active layer from being damaged and conduct current, and further solve the problem that the nanowire active layer is prone to being influenced by the dry etching process to cause damage to the nanowire active layer when the via hole for conducting a source-drain and the nanowire active layer is formed through the dry etching process in the related art.

Obviously, those skilled in the art can make various modifications and variations to the present disclosure without departing from the spirit and scope of the present disclosure. In this way, if these modifications and variations of the present disclosure fall within the scope of the claims of the present disclosure and their equivalent art, the present disclosure also intends to include these modifications and variations.

What is claimed is:

1. A method for manufacturing a thin film transistor, comprising:
forming a nanowire active layer on one side of a base substrate;
forming a conductive protective layer on one side of the nanowire active layer away from the base substrate;
forming an insulating layer on one side of the protective layer away from the nanowire active layer;
forming a first via hole exposing a first region of the protective layer and a second via hole exposing a second region of the protective layer by etching the insulating layer using a dry etching process, wherein the first region and the second region are not overlapped with each other; and
forming a source-drain layer on one side of the insulating layer away from the protective layer, wherein the source-drain layer comprises a first electrode and a second electrode, the first electrode is electrically conducted with the nanowire active layer through the first via hole, and the second electrode is electrically conducted with the nanowire active layer through the second via hole.

2. The method according to claim 1, wherein after etching the insulating layer using the dry etching process, and before forming the source-drain layer on the side of the insulating layer away from the protective layer, the method further comprises:
removing the protective layer in the first region, and removing the protective layer in the second region by etching the protective layer using a wet etching process.

3. The method according to claim 1, wherein the forming the nanowire active layer on the side of the base substrate comprises:
forming a patterned first film layer with at least one guide groove on one side of the base substrate;
forming metal guide particles at one end of the guide groove;
forming an amorphous silicon thin film on one side of the metal guide particles away from the first film layer, and annealing the amorphous silicon thin film to form a silicon nanowire in the guide groove; and
forming the nanowire active layer by patterning the annealed amorphous silicon thin film, wherein a pattern of the nanowire active layer is complementary to that of the first film layer.

4. The method according to claim 2, wherein the forming the nanowire active layer on the side of the base substrate comprises:
forming a patterned first film layer with at least one guide groove on one side of the base substrate;
forming metal guide particles at one end of the guide groove;
forming an amorphous silicon thin film on one side of the metal guide particles away from the first film layer, and annealing the amorphous silicon thin film to form a silicon nanowire in the guide groove; and
forming the nanowire active layer by patterning the annealed amorphous silicon thin film, wherein a pattern of the nanowire active layer is complementary to that of the first film layer.

5. The method according to claim 3, wherein the forming the metal guide particles at the end of the guide groove comprises:
forming a second thin film on one side of the first film layer away from the base substrate;
removing the second thin film in other regions except a region where one end of the groove is located; and
forming the metal guide particles by performing hydrogen plasma treatment on the retained second thin film.

6. The method according to claim 4, wherein forming the metal guide particles at the one end of the guide groove comprises:
forming a second thin film on one side of the first film layer away from the base substrate;
removing the second thin film in other regions except a region where one end of the groove is located; and
forming the metal guide particles by performing hydrogen plasma treatment on the retained second thin film.

7. The method according to claim 5, wherein the forming the second thin film on the side of the first film layer away from the base substrate comprises:
forming indium tin oxide on the side of the first film layer away from the base substrate.

8. The method according to claim 1, wherein the forming the conductive protective layer on the side of the nanowire active layer away from the base substrate comprises:
forming molybdenum, copper, aluminum or indium tin oxide on the side of the nanowire active layer away from the base substrate.

9. The method according to claim 1, wherein the forming the insulating layer on one side of the protective layer away from the nanowire active layer comprises:
forming a gate insulating layer on one side of the protective layer away from the nanowire active layer; and
forming an interlayer dielectric layer on one side of the gate insulating layer away from the nanowire active layer.

10. The method according to claim 9, wherein after the forming the gate insulating layer on the side of the protective layer away from the nanowire active layer, and before the forming the interlayer dielectric layer on the side of the gate insulating layer away from the nanowire active layer, the method further comprises:
forming a gate on one side of the gate insulating layer away from the nanowire active layer.

11. A thin film transistor, comprising:
a base substrate;
a nanowire active layer on one side of the base substrate;
a conductive protective layer on one side of the nanowire active layer away from the base substrate;
an insulating layer on one side of the protective layer away from the nanowire active layer, wherein the insulating layer has a first via hole exposing a first region of the protective layer and a second via hole exposing a second region of the protective layer, and the first region and the second region are not overlapped with each other; and
a source-drain layer on one side of the insulating layer away from the protective layer, wherein the source-drain layer comprises a first electrode and a second electrode, the first electrode is electrically conducted with the nanowire active layer through the first via hole, and the second electrode is electrically conducted with the nanowire active layer through the second via hole.

12. The thin film transistor according to claim 11, wherein the protective layer has a first hollowed-out structure in the first region, and the protective layer has a second hollowed-out structure in the second region; and an orthographic projection of the first hollowed-out structure on the base substrate is coincided with an orthographic projection of the first via hole on the base substrate, and an orthographic projection of the second hollowed-out structure on the base substrate is coincided with an orthographic projection of the second via hole on the base substrate.

13. The thin film transistor according to claim 11, wherein the thin film transistor further comprises: a patterned first film layer between the base substrate and the nanowire active layer, the first film layer has at least one guide groove, and a pattern of the first film layer is complementary to that of the nanowire active layer.

14. The thin film transistor according to claim 12, wherein the thin film transistor further comprises: a patterned first film layer between the base substrate and the nanowire active layer, the first film layer has at least one guide groove, and a pattern of the first film layer is complementary to that of the nanowire active layer.

15. The thin film transistor according to claim 13, wherein metal guide particles are formed in one end of the guide groove by hydrogen plasma treatment on a second thin film.

16. The thin film transistor according to claim 15, wherein a material of the second thin film is indium tin oxide; and the nanowire active layer comprises the metal guide particles of indium.

17. The thin film transistor according to claim 11, wherein a material of the protective layer is molybdenum, copper, aluminum or indium tin oxide.

18. The thin film transistor according to claim 11, wherein the insulating layer comprises a gate insulating layer and an interlayer dielectric layer on one side of the gate insulating layer away from the nanowire active layer; and
a gate is further arranged between the gate insulating layer and the interlayer dielectric layer.

19. An array substrate, comprising the thin film transistor according to claim 11.

20. A display device, comprising the array substrate according to claim 19.
